(19) United States
(12) Patent Application Publication
(10) Pub. No.: US 2025/0159836 A1
(43) Pub. Date: May 15, 2025

(54) DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/937,379

(22) Filed: Nov. 5, 2024

(30) Foreign Application Priority Data
Nov. 10, 2023 (CN) 202311499087.7

(51) Int. Cl. H05K 7/14

(52) U.S. Cl. CPC H05K 7/1492

(57) ABSTRACT

The present disclosure discloses a data center, which includes: a first layer architecture comprising a plurality of power distribution units; a second layer architecture superposed above the first layer architecture and comprising a plurality of data units, where the power distribution unit is configured to supply power to the data unit corresponding to an upper or lower part of the power distribution unit; and a transport elevator connecting the first layer structure and the second layer structure, where the transport elevator has a first end and a second end arranged opposite to each other. The plurality of power distribution units are wrapped around an outer side of the first end of the transport elevator, and the plurality of data units are wrapped around an outer side of the second end of the transport elevator.

### CROSS REFERENCE TO RELATED APPLICATION

This application claims priority to Chinese Patent Application No. 202311499087.7, titled “DATA CENTER” and filed to the China National Intellectual Property Administration on Nov. 10, 2023, the entire contents of which are incorporated herein by reference.

### TECHNICAL FIELD

Embodiments of the present disclosure relate to the field of data center technology, and more particularly, to a data center.

### BACKGROUND

With the development of information technologies, data centers play an increasingly important role, which not only include computer systems and other corollary equipment, but also include redundant data communication connection and environmental control equipment, and various security devices.

A related data center is formed by splicing containers, which has the characteristics of lower cost, higher energy efficiency, flexibility, and rapid deployment, and thus has gradually been adopted by major device manufacturers.

However, the related data center has lower assembly efficiency.

### SUMMARY

An objective of embodiments of the present disclosure is to provide a data center, which can solve a problem of lower assembly efficiency in data centers.

To achieve the above objective, one aspect of the embodiments of the present disclosure provides a data center, which includes: a first layer architecture comprising a plurality of power distribution units, where each of the plurality of power distribution units includes a power distribution box and a power distribution device group arranged in the power distribution box; a second layer architecture superposed above the first layer architecture, where the second layer architecture includes a plurality of data units, each of the plurality of data units includes a data box and a data server group arranged in the data box, and the power distribution unit is configured to supply power to the data unit corresponding to an upper or lower part of the power distribution unit; and a transport elevator connecting the first layer structure and the second layer structure, where the transport elevator has a first end and a second end arranged opposite to each other. The plurality of power distribution units are wrapped around an outer side of the first end of the transport elevator, and the plurality of data units are wrapped around an outer side of the second end of the transport elevator.

Alternatively, the plurality of power distribution units are annularly distributed around the first end of the transport elevator, and the plurality of data units are annularly distributed around the second end of the transport elevator; or the plurality of power distribution units are distributed in a concentric circle around the first end of the transport elevator, and the plurality of data units are distributed in a concentric circle around the second end of the transport elevator.

Alternatively, the plurality of power distribution units are arranged on two sides of the first end of the transport elevator along a first direction, and the plurality of data units are arranged on two sides of the second end of the transport elevator along the first direction.

Alternatively, there are a plurality of transport elevators arranged at intervals along a second direction, where the second direction intersects the first direction. The plurality of power distribution units are divided into a plurality of groups, and each of the plurality of groups of the power distribution units are arranged on the two sides of the first end of one of the plurality of transport elevators. The plurality of data units are divided into a plurality of groups, and each of the plurality of groups of the data units are arranged on the two sides of the second end of one of the plurality of the transport elevators.

Alternatively, the first layer architecture also includes a plurality of incoming units arranged on two sides of the plurality of power distribution units along the first direction. Each of the plurality of incoming units includes an inlet box and a high-voltage incoming device arranged inside the inlet box.

The first layer architecture also includes a plurality of fresh air units arranged on the two sides of the plurality of power distribution units along the first direction. Each of the plurality of fresh air units includes a fresh air box and a fresh air device arranged in the fresh air box, where the fresh air device is communicated with the first layer structure and outside world, and the fresh air device is configured to ventilate the first layer structure.

The first layer architecture also includes a super-core machine room, where the super-core machine room includes a super-core box and a super-core server group arranged in the super-core box. The super-core machine room is arranged on at least one side of the plurality of power distribution units along the first direction.

Alternatively, the power distribution device group includes a medium-voltage power distribution module and a low-voltage power distribution module electrically connected to each other. Both the medium-voltage power distribution module and the low-voltage power distribution module extend along the first direction, and the medium-voltage power distribution module and the low-voltage power distribution module are arranged at intervals along the second direction, which intersects the first direction.

Alternatively, the low-voltage power distribution module includes a transformer, an incoming cabinet, an uninterruptible power supply (UPS), and an outgoing cabinet sequentially arranged along the first direction.

The medium-voltage power distribution module includes a medium-voltage power distribution cabinet and a power conversion system (PLC) sequentially arranged along the first direction.

Alternatively, the data server group includes a plurality of data cabins arranged at intervals in an array. Each of the plurality of data cabins includes a cabin body and an IT cabinet and a wind wall arranged in an inner cavity of the cabin body, where the IT cabinet is arranged along the first direction, the wind wall is spaced on one side of the IT cabinet along the second direction, and an air duct for air flow is formed between the IT cabinet and the wind wall.

Alternatively, the data center also includes a third layer architecture arranged above the second layer architecture, where the third layer architecture includes a plurality of outdoor units arranged in an array, and each of the plurality of outdoor units is communicated with the wind wall.

Alternatively, the first layer architecture also includes a first auxiliary unit, and the plurality of power distribution units are wrapped around an outer side of the first auxiliary unit. The first auxiliary unit includes at least one of a first sanitation room, a storage room, a duty room, a fire control room, a first strong or weak electricity room, an entrance hall, and an unloading hall.

The second layer architecture also includes a second auxiliary unit, and the plurality of data units are wrapped around an outer side of the second auxiliary unit. The second auxiliary unit includes at least one of a second sanitation room, a second strong or weak electricity room, an operation and maintenance room, a fresh air room, and a weak electricity machine room.

The transport elevator connects the first auxiliary unit and the second auxiliary unit.

To sum up, in the data center provided in the embodiments of the present disclosure, the plurality of data units are arranged above the plurality of power distribution units, the first layer architecture integrates devices related to electrical energy, and the second layer architecture integrates devices related to computing and processing. In this way, types of construction and devices required for each floor are relatively single, which can avoid cross construction on the same floor and shorten construction period.

In addition, compared to a transport elevator arranged at an end, the transport elevator provided in the embodiments of the present disclosure is arranged in a middle, such that a user can quickly reach a designated location from the transport elevator, thereby reducing a travel path and making it easier for overhaul, construction, and operation and maintenance.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a longitudinal structure of a data center according to an embodiment of the present disclosure;

FIG. 2 is a schematic diagram of a first layer architecture according to an embodiment of the present disclosure;

FIG. 3 is a schematic diagram of a medium-voltage power distribution module according to an embodiment of the present disclosure;

FIG. 4 is a schematic diagram of a low-voltage power distribution module according to an embodiment of the present disclosure;

FIG. 5 is a schematic diagram of a second layer architecture according to an embodiment of the present disclosure;

FIG. 6 is a schematic diagram of a data cabin according to an embodiment of the present disclosure; and

FIG. 7 is a schematic diagram of a third layer architecture according to an embodiment of the present disclosure.

### REFERENCE NUMERALS IN THE ACCOMPANYING DRAWINGS

first layer architecture 100; power distribution unit 110; medium-voltage power distribution module 111; medium-voltage power distribution cabinet 1111; PLC 1112; low-voltage power distribution module 112; transformer 1121; incoming cabinet 1122; UPS 1123; outgoing cabinet 1124; incoming unit 120; fresh air unit 130; super-core machine room 140; first auxiliary unit 150; first sanitation room 151; storage room 152; duty room 153; fire control room 154; first strong or weak electricity room 155; entrance hall 156; unloading hall 157; first aisle 160; alarm valve unit 170; first reserve unit 180; steel cylinder unit 190;
second layer architecture 200; data unit 210; second auxiliary unit 220; second sanitation room 221; second strong or weak electricity room 222; operation and maintenance room 223; fresh air room 224; weak electricity machine room 225; second aisle 230; second reserve unit 240;
third layer architecture 300; outdoor unit 310; third strong or weak electricity room 320; high voltage room 330;
transport elevator 400;
data cabin 500; cabin body 510; IT cabinet 520; wind wall 530; air duct 540;
energy source unit 600; and
water tank 700.

### DETAILED DESCRIPTION

As described in the background technology, data centers in related technologies have a problem of lower assembly efficiency. Based on inventors' research, it is found that reasons for this problem are as below. A related data center has a plurality of floors, each of which is equipped with machine room areas, power distribution areas, and refrigeration areas, and the plurality of floors are communicated with each other by means of elevators or stairs arranged at ends. During construction, builders transport devices through the elevators or stairs arranged at the ends, resulting in a longer walking path. In addition, each floor of the data center requires power distribution cables and air ducts, so each floor requires collaborative operation in different types of construction, which adversely affects construction efficiency.

In response to the above technical problems, embodiments of the present disclosure provide a data center. A plurality of data units are arranged above a plurality of power distribution units, a first layer architecture integrates devices related to electrical energy, and a second layer architecture integrates devices related to computing and processing. In this way, types of construction and devices required for each floor are relatively single, which can avoid cross construction on the same floor and shorten construction period. In addition, compared to the related technologies, a transport elevator provided in the embodiments of the present disclosure is arranged in a middle, such that a user can quickly reach a designated location from the transport elevator, thereby reducing a travel path and making it easier for overhaul, construction, and operation and maintenance.

To make the objectives, technical solutions, and advantages of the embodiments of the present disclosure clearer, the technical solutions in the embodiments of the present disclosure will be described clearly and completely below with reference to the accompanying drawings in the embodiments of the present disclosure. Apparently, the described embodiments are some but not all of the embodiments of the present disclosure.

All other embodiments obtained by a person of ordinary skill in the art based on the embodiments of the present disclosure without creative efforts shall fall within the protection scope of the present disclosure. The following embodiments and features thereof may be combined with each other on a non-conflict basis.

First, a brief introduction is made to terms involved in the embodiments of the present disclosure.

A modular box is a unified box based on a size specification of a container or frame box. The container is a standardized vessel having large loading capacity, such as a forty-foot cargo container. The frame box is a container having no roof or walls on two sides. In the embodiments of the present disclosure, the modular box is used for accommodating an IT device, a server, a refrigeration system, a monitoring system and the like related to the data center. A power distribution box, an energy source box, a data box, an inlet box, a fresh air box, a super-core box, a first auxiliary box, a second auxiliary box and so on mentioned below may be the modular box.

The modular box may include steel, a roof panel, and a wall panel. The steel may be selected from an H-shaped steel column, an H-shaped steel beam, a Z-shaped steel beam or the like may be erected into a lightweight portal rigid frame structure. The lightweight portal rigid frame structure, the roof panel, and the wall panel may be constructed to form indoor space. Electrical devices and household tools and so on may be accommodated in the indoor space. Alternatively, the roof panel and the wall panel may be made of fire-resistant panels such as rock wool composite sandwich panels. It is to be noted that in the embodiments of the present disclosure, one modular box may be used for one type of functional device, and one modular box may also be shared by a variety of functional devices. In practical applications, production, installation, and transportation of the modular box may be comprehensively considered to reasonably determine dimensions of building components.

Prefabrication of the data center is a physical infrastructure system of the data center that has been pre-designed, assembled, integrated tested in advance, and is transported to the data center site as a standardized “plug-and-play” module.

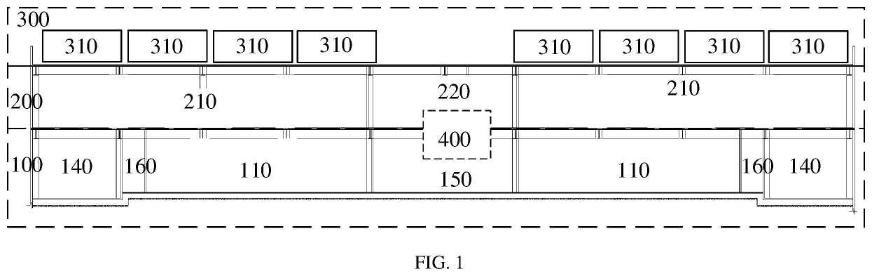

FIG. 1 is a schematic diagram of a longitudinal structure of a data center according to an embodiment of the present disclosure. Referring to FIG. 1, the data center may include a first layer architecture and a second layer architecture positioned above the first layer architecture. The first layer architecture may include a plurality of power distribution units, the second layer architecture may include a plurality of data units, and each of the plurality of power distribution units may supply power to the data unit corresponding to an upper or lower part of the power distribution unit. In this way, the first layer architecture integrates devices related to electrical energy, and the second layer architecture integrates devices related to computing and processing. Thus, types of construction and devices required for each floor are relatively single, which can avoid cross construction on the same floor and shorten construction period.

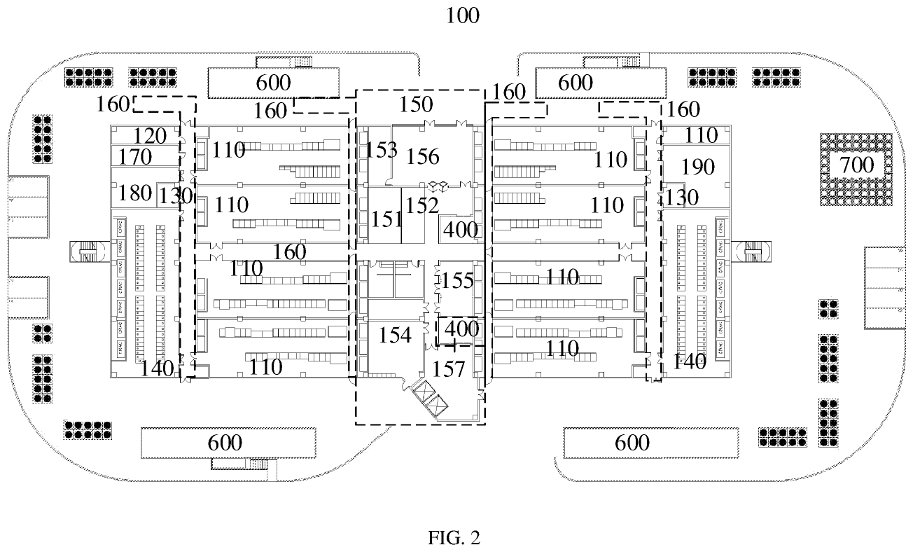

FIG. 2 is a schematic diagram of a first layer architecture according to an embodiment of the present disclosure. Referring to FIG. 2, each of the plurality of power distribution units includes a power distribution box and a power distribution device group arranged in the power distribution box. An input end of the power distribution device group may be electrically connected to an external power supply, an energy source unit, or a power generation unit. The energy source unit may be an energy storage apparatus. During normal operation of the external power supply, a portion of electrical energy from the external power supply may be supplied to the data center through the power distribution device group, and another portion of the electrical energy may be stored in the energy source unit. When the external power supply goes wrong, power may be supplied to the data center by the energy source unit and/or the power generation unit.

To facilitate construction of the energy source unit, the energy source unit may be arranged below the first layer architecture. To make it easier to cool down the energy source unit, the energy source unit may be arranged underground. The energy source unit may include an energy source box and an energy device group arranged in the energy source box. The energy device group may include at least one of a plurality of battery modules, a battery bus module, a battery management module, a power distribution modules, and a power conversion system (PCS) module. In addition, the energy device group may be cooled down by means of air cooling, liquid cooling, or mixed air-liquid cooling, etc. When the liquid cooling or mixed air-liquid cooling is used, the data center may also include a water tank, which may be arranged on an outer side of the first layer architecture. In addition, the energy source unit may also include at least one of a fire control module, a strong or weak electricity bridge module, a lighting module, and a monitoring module.

In addition, the energy source box may use a cabinet to accommodate each module. In one embodiment, a single cabinet corresponds to a single module. For example, one cabinet accommodates the battery module, and another cabinet accommodates the battery bus module. In another embodiment, a single cabinet corresponds to a plurality of modules. For example, one cabinet accommodates the battery module and the battery bus module, and one cabinet accommodates the battery management module and the power distribution module. In still another embodiment, a plurality of cabinets correspond to a plurality of modules. For example, one cabinet accommodates a portion of circuits of the battery module and a portion of circuits of the battery bus module, and another cabinet accommodates a portion of circuits of the battery module and a portion of circuits of the battery bus module. It is worth noting that both number of cabinets inside the energy source box and order in which the cabinets are placed are set according to an energy source required for an actual data center and stipulations related to power supply and distribution.

In addition, the power generation unit can generate power through generators, solar energy, hydroenergy, wind energy, tidal energy, ocean energy, hydrogen energy, and geothermal energy, etc. When generating power through a generator, the power generation unit may include a generator, an oil storage tank, and a non-stop refueling system, etc. The generator may be a diesel generator, the oil storage tank can supply fuel to the generator, and the non-stop refueling system can replenish fuel for the oil storage tank in the power generation process.

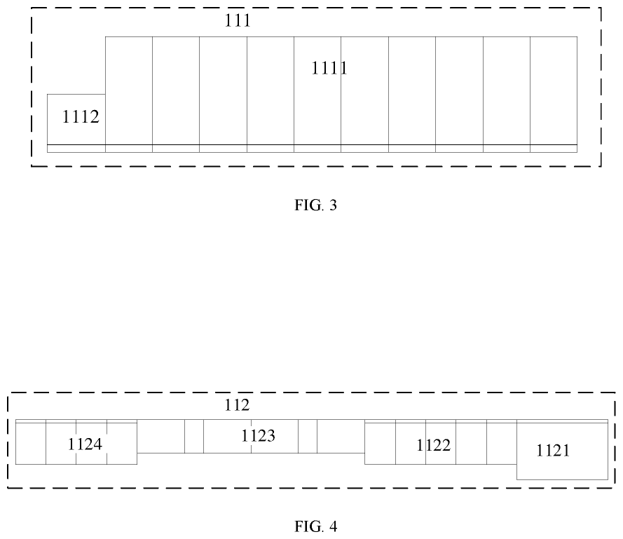

FIG. 3 is a schematic diagram of a medium-voltage power distribution module according to an embodiment of the present disclosure, and FIG. 4 is a schematic diagram of a low-voltage power distribution module according to an embodiment of the present disclosure. Referring to FIGS. 2 to 4, the power distribution device group may include the medium-voltage power distribution module and the low-voltage power distribution module that are electrically connected to each other.

To facilitate overhaul and maximize the use of rectangular space of the power distribution box, alternatively, both the medium-voltage power distribution module and the low-voltage power distribution module may extend along the first direction (a left-right direction as shown in FIGS. 2 to 4), and the medium-voltage power distribution module and the low-voltage power distribution module are arranged at intervals along the second direction (a front-rear direction as shown in FIG. 2). The first direction may be a length direction of a cross-section of the power distribution box, and the second direction may be a width direction of the cross-section of the power distribution box.

Referring to FIG. 3, the medium-voltage power distribution module may include at least one medium-voltage power distribution cabinet, and the medium-voltage power distribution cabinet may include at least one of an incoming cabinet, a metering cabinet, an outgoing cabinet, a potential transformer (PT), a lightning protection grounding cabinet, and a bus tie cabinet. The incoming cabinet is a switch cabinet that introduces an external power source. The metering cabinet is an electrical metering apparatus. The outgoing cabinet is a switch cabinet that distributes electrical energy. The PT and the lightning protection grounding cabinet are devices used for detecting a bus voltage to achieve protection functions. The bus tie cabinet is an optional extension cabinet. When a feeder cabinet needs to be additionally provided due to changes in internal power supply lines, the feeder cabinet may be additionally arranged on the bus tie cabinet. When the data center also uses a diesel power generation modular box to generate power the medium-voltage power distribution module may also include a medium-voltage diesel generator incoming cabinet, which may be electrically connected to the power generation unit. When there are a plurality of medium-voltage power distribution cabinets, the plurality of medium-voltage power distribution cabinets may be sequentially arranged along the first direction (the left-right direction as shown in FIG. 3).

Alternatively, the medium-voltage power distribution module may also include a programmable logic controller (PLC). The PLC may be electrically connected to the medium-voltage power distribution cabinet, and the PLC and the medium-voltage power distribution cabinet may be sequentially arranged along the first direction.

In addition, referring to FIG. 4, the low-voltage power distribution module may include at least one low-voltage power distribution cabinet, which may include at least one of an incoming cabinet, an outgoing cabinet, a compensation cabinet, and a low-voltage power distribution cabinet that functions as a direct current (DC). Alternatively, an uninterruptible power supply (UPS) may also be electrically connected between the incoming cabinet and the outgoing cabinet, to ensure operation of the data center.

Alternatively, the transformer can change the voltage. The transformer may be included in the medium-voltage power distribution module, or may be included in the low-voltage power distribution module, or may be placed separately. The embodiments of the present disclosure do not limit a placement position of the transformer, and FIG. 4 only shows an example where the transformer is included in the low-voltage power distribution module.

Alternatively, the first layer architecture may also include an incoming unit. The incoming unit may include an inlet box and a high-voltage incoming device arranged in the inlet box. When the power supply has a high voltage, the high-voltage incoming device can convert the high voltage into a low voltage and transmit the low voltage to the medium-voltage power distribution module. Alternatively, there may be a plurality of incoming units, and the plurality of incoming units may be arranged on outer sides of the plurality of power distribution units to facilitate cable laying. For example, in FIG. 1 and FIG. 2, the data center is shaped like a rectangle, and a length direction of the rectangle is arranged along the first direction (the left-right direction as shown in FIG. 1 and FIG. 2). In FIG. 2, the plurality of power distribution units are sequentially arranged along the first direction. The plurality of incoming units may be arranged on two sides of the plurality of power distribution units along the first direction, and the incoming units may be connected to the power distribution units on the same side through laid cables to reduce cable length between the incoming units and the power distribution units. In addition, to facilitate the user's movement, a first aisle may be formed between the incoming unit and the power distribution unit. Both the inlet box and the power distribution box are provided with a door facing towards the first aisle.

Alternatively, the first layer architecture may also include a plurality of fresh air units. Each of the plurality of fresh air units may include a fresh air box and a fresh air device arranged in the fresh air box. The fresh air device may be communicated with the first layer architecture and the outside world, and the fresh air device is used for ventilating the first layer architecture. The plurality of fresh air units may be arranged on the outer sides of the plurality of power distribution units. For example, in FIG. 2, the plurality of fresh air units may be arranged on the two sides of the plurality of power distribution units along the first direction, such that the plurality of power distribution units may be centralized, which is advantageous to divisional layout. In addition, to facilitate the user's movement, the first aisle may be formed between the fresh air unit and the power distribution unit. Both the fresh air box and the power distribution box are provided with a door facing towards the first aisle.

Alternatively, the first layer architecture may also include a super-core machine room, which may include a super-core box and a super-core server group arranged in the super-core box. The super-core server group can include a plurality of cabinet servers and a cooling apparatus. The cooling apparatus can cool down the plurality of cabinet servers by means of air cooling, liquid cooling, or mixed air-liquid cooling, etc. When the liquid cooling or mixed air-liquid cooling is used, the data center may also include a water tank, which may be arranged on the outer side of the first layer architecture. It is to be noted that the super-core server group has a larger volume and larger handling capacity compared to the data server group arranged in the second layer architecture. In addition, the super-core machine room may be arranged on the outer sides of the plurality of power distribution units. For example, in FIG. 2, the super-core machine room may be arranged on at least one side of the plurality of power distribution units along the first direction, such that the plurality of power distribution units may be centralized, which is advantageous to divisional layout. In addition, to facilitate the user's movement, the first aisle may be formed between the super-core machine room and the power distribution unit. Both the super-core box and the power distribution box are provided with a door facing towards the first aisle.

Alternatively, the incoming unit, the fresh air unit, and the super-core machine room mentioned above may be sequentially arranged along the second direction. The second direction may intersect the first direction. FIG. 2 shows an example where the first direction is the left-right direction, and the second direction is the front-rear direction.

Alternatively, the first layer architecture may also include parts not frequently used, such as an alarm valve unit, a first reserve unit, and a steel cylinder unit. These parts not frequently used may be arranged at an edge of the first layer architecture. For example, in FIG. 2, these parts not frequently used may be arranged on at least one side of the plurality of power distribution units along the first direction, such that the plurality of power distribution units may be centralized, which is advantageous to divisional layout. In addition, to facilitate the user's movement, the first aisle may be formed between these parts not frequently used and the power distribution unit. Boxes of these parts not frequently used and the power distribution box are provided with a door facing towards the first aisle, respectively.

Alternatively, the first layer architecture may also include a first auxiliary unit, and the plurality of power distribution units may be wrapped around the outer side of the first layer architecture. The plurality of power distribution units may be arranged in an array. For example, in FIG. 2, the plurality of power distribution units are arranged on two sides of the first auxiliary unit along the first direction, or the plurality of power distribution units may be annularly distributed or may be distributed in a concentric circle.

The first auxiliary unit may include rooms frequently used by the user, such as a first sanitation room, a storage room, a duty room, a first strong or weak electricity room, an entrance hall, and an unloading hall. In this way, it is convenient for the user to travel from the first auxiliary unit to the power distribution unit at a certain location. In addition, the first auxiliary unit may also include a fire control room, which can allow the user to quickly extinguish fire at a designated location in case of a fire disaster. It is worth noting that these rooms may be formed by one or more first auxiliary boxes. Referring to FIG. 2, to facilitate the user's movement, the first aisle may be formed between the first auxiliary unit and the power distribution unit. Both the first auxiliary box and the power distribution box are provided with a door facing towards the first aisle.

Referring to FIG. 1, the data center provided in the embodiments of the present disclosure may also include a transport elevator, which may connect the first layer architecture and the second layer architecture. Specifically, the transport elevator may have a first end and a second end that are arranged opposite to each other. The plurality of power distribution units may be wrapped around an outer side of the first end of the transport elevator, and the plurality of data units may be wrapped around an outer side of the second end of the transport elevator. In this way, compared to a transport elevator arranged at an end, the transport elevator provided in the embodiments of the present disclosure is arranged in a middle, such that the user can quickly reach the designated location from the transport elevator, thereby reducing the travel path and making it easier for overhaul, construction, and operation and maintenance, and also facilitating transportation of new devices.

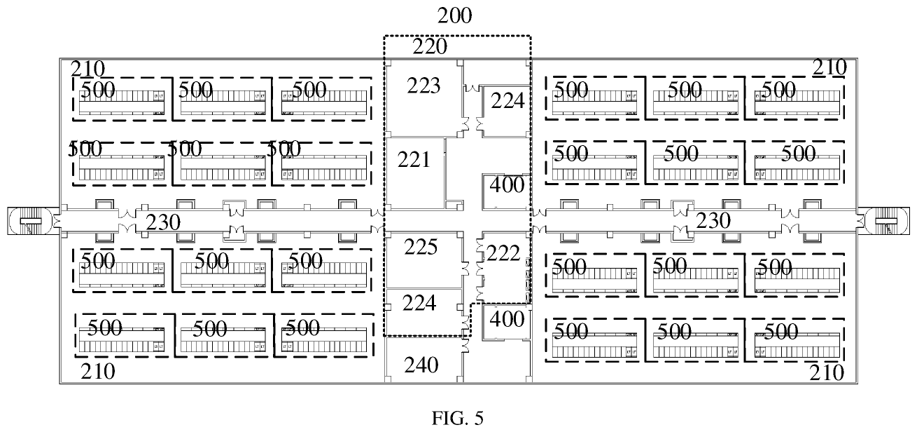

For example, the plurality of power distribution units/data units may be arranged in a matrix format. For example, in FIG. 2, the plurality of power distribution units are arranged on two sides along the first direction, and in FIG. 5, the plurality of data units are arranged on two sides of the second end of the transport elevator along the first direction. Alternatively, there are a plurality of transport elevators, and the plurality of transport elevators are arranged at intervals along the second direction (the front-rear direction as shown in FIG. 2). The plurality of power distribution units may be divided into a plurality of groups, and each of the plurality of groups of the power distribution units may be arranged on the two sides of the first end of one of the plurality of transport elevators. For example, in FIG. 2, there are two transport elevators, where the first end of one of the two transport elevators is arranged in the unloading hall, and the first end of the other one of the two transport elevators is arranged in the entrance hall. Referring to FIG. 5, the plurality of data units may be divided into a plurality of groups, and each of the plurality of groups of the data units may be arranged on two sides of the second end of one of the transport elevators. For example, in FIG. 5, the first end of one of the transport elevators is arranged on a rear side of the second auxiliary unit, and the second end of the other one of the transport elevators is arranged on a front sided of the second auxiliary unit.

Alternatively, in FIG. 2, a first aisle may be formed between adjacent two groups of power distribution units, and a door is provided on the power distribution box of the power distribution unit adjacent to the first aisle for the user to walk through and quickly enter the power distribution unit. In addition, in FIG. 5, a second aisle may be formed between adjacent two groups of data units, and a door is provided on the data box of the data unit adjacent to the second aisle for the user to walk through and quickly enter the data unit.

For another example, the plurality of power distribution units/data units may be annularly distributed or may be distributed in a concentric circle.

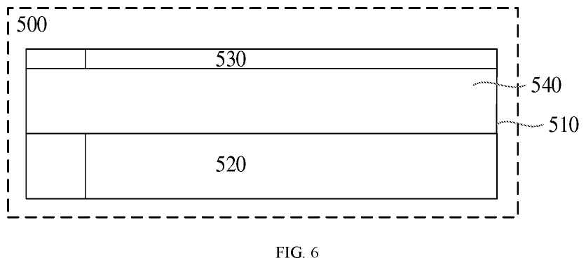

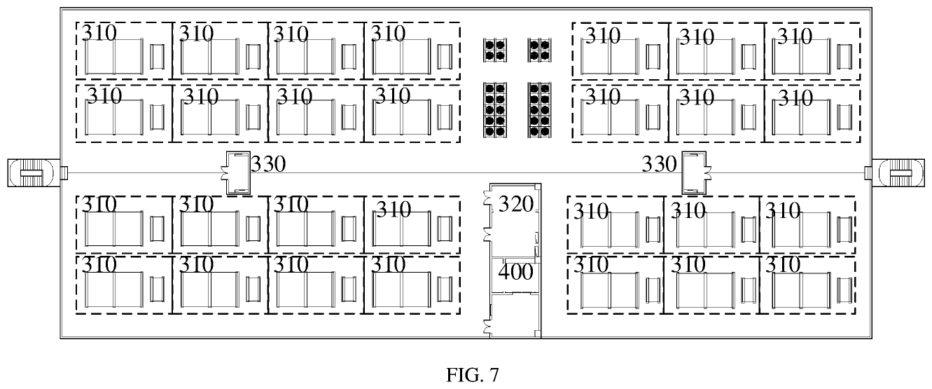

FIG. 5 is a schematic diagram of a second layer architecture according to an embodiment of the present disclosure. Referring to FIG. 5, each of the data units may include a data box and a data server group arranged in the data box. The data server group may include a plurality of data cabins arranged at intervals in an array. Referring to FIG. 6, each of the plurality of data cabins may include a cabin body and an IT cabinet arranged in an inner cavity of the cabin body. The IT cabinet may be cooled down by means of air cooling, liquid cooling, or mixed air-liquid cooling, etc. When the liquid cooling or mixed air-liquid cooling is used, the data center may also include a water tank, which may be arranged on the outer side of the first layer architecture. When the IT cabinet is cooled down by means of a wind wall, the IT cabinet may extend along the first direction. The wind wall may be spaced on one side of the IT cabinet along the second direction, and an air duct for air flow is formed between the IT cabinet and the wind wall. In addition, referring to FIG. 1 and FIG. 7, the data center provided in the embodiments of the present disclosure may also include a third layer architecture, which may be arranged above the second layer architecture. The third layer architecture may include a plurality of outdoor units arranged in an array, and each of the plurality of outdoor units may be communicated with the wind wall, to facilitate flow of a heat transfer media such as a refrigerant. In addition, the transport elevator may also connect the first layer structure, the second layer structure, and the third layer structure.

With continued reference to FIG. 5, alternatively, the second layer architecture may also include a second auxiliary unit, and the plurality of data units may be wrapped around the outer side of the second auxiliary unit. The plurality of data units may be arranged in an array. For example, in FIG. 5, the plurality of data units are arranged on the two sides of the second auxiliary unit along the first direction; or the plurality of data units may be annularly distributed or may be distributed in a concentric circle.

The second auxiliary unit may include rooms for maintenance, living, etc., such as a second sanitation room, a second strong or weak electricity room, an operation and maintenance room, a weak electricity machine room, and a fresh air room, to concentrate the user's living and working areas in the middle of the plurality of data units, to make it convenient for the user to live and reach a certain data unit. It is worth noting that these rooms may be formed by one or more second auxiliary boxes. Referring to FIG. 5, to facilitate the user's movement, a second aisle may be formed between the second auxiliary unit and the data unit. Both the second auxiliary box and the data box are provided with a door facing towards the second aisle.

Referring to FIG. 5, the second layer architecture may also include a second reserve unit. The second reserve unit may be arranged on one side of the second auxiliary unit, or may be doped with the second auxiliary unit.

Referring to FIG. 2 and FIG. 5, to facilitate the cable laying, the first strong or weak electricity room and the second strong or weak electricity room may be in top-bottom correspondence. In addition, when there exists the third layer architecture, the third layer architecture may also include a third strong or weak electricity room, where the first strong or weak electricity room, the second strong or weak electricity room, and the third strong or weak electricity room may be in top-middle-bottom correspondence.

Alternatively, the transport elevator may be a stair or an elevator. Exterior stairs arranged oppositely may be provided on the outer side of the data center, making it convenient for reaching corresponding floors from a lateral side.

The terms such as “upper” and “lower” for describing relative positional relationships of various structures in the drawings are merely for the purpose of concise description rather than limiting the implementable scope of the present disclosure. The changes or adjustments of the relative relationship without a substantial modification to the technical solutions are regarded as being covered by the implementable scope of the present disclosure.

It is to be noted that in the present disclosure, unless specified or limited otherwise, a first feature “on” or “below” a second feature may include an embodiment in which the first feature is in direct contact with the second feature, and may also include an embodiment in which the first feature and the second feature are in indirect contact via an intermediary. Furthermore, a first feature “on,” “above,” or “on top of” a second feature may include an embodiment in which the first feature is right or obliquely “on,” “above,” or “on top of” the second feature, or just means that the first feature is at a height higher than that of the second feature. A first feature “below,” “under,” or “on bottom of” a second feature may include an embodiment in which the first feature is right or obliquely “below,” “under,” or “on bottom of” the second feature, or just means that the first feature is at a height lower than that of the second feature.

In addition, in the present disclosure, unless specified or limited otherwise, terms “mounted”, “connected”, “coupled”, “fixed” and so on should be understood in a broad sense, which may be, for example, a fixed connection, a detachable connection or integrated connection, a direct connection or indirect connection by means of an intermediary, an internal communication between two elements or an interaction relationship between two elements. The specific significations of the above terms in the present disclosure may be understood in the light of specific conditions by persons of ordinary skill in the art.

Reference throughout this specification to the terms “an embodiment,” “some embodiments,” “an exemplary embodiment,” “an example,” “a specific example,” or “some examples,” means that a specific feature, structure, material, or characteristic described in connection with the embodiment or example is included in at least one embodiment or example of the present disclosure. The schematic representation of the above terms throughout this specification are not necessarily referring to the same embodiment or example. Furthermore, the specific features, structures, materials, or characteristics set forth may be combined in any suitable manner in one or more embodiments or examples.

Finally, it is to be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A data center comprising:
a first layer architecture comprising a plurality of power distribution units, each of the plurality of power distribution units comprising a power distribution box and a power distribution device group arranged in the power distribution box;
a second layer architecture superposed above the first layer architecture, the second layer architecture comprising a plurality of data units, each of the plurality of data units comprising a data box and a data server group arranged in the data box; the power distribution unit being configured to supply power to the data unit corresponding to an upper or lower part of the power distribution unit; and
a transport elevator connecting the first layer structure and the second layer structure, the transport elevator having a first end and a second end arranged opposite to each other; the plurality of power distribution units being wrapped around an outer side of the first end of the transport elevator, and the plurality of data units being wrapped around an outer side of the second end of the transport elevator.

2. The data center according to claim 1, wherein the plurality of power distribution units are annularly distributed around the first end of the transport elevator, and the plurality of data units are annularly distributed around the second end of the transport elevator; or
the plurality of power distribution units are distributed in a concentric circle around the first end of the transport elevator, and the plurality of data units are distributed in a concentric circle around the second end of the transport elevator.

3. The data center according to claim 1, wherein the plurality of power distribution units are arranged on two sides of the first end of the transport elevator along a first direction, and the plurality of data units are arranged on two sides of the second end of the transport elevator along the first direction.

4. The data center according to claim 3, wherein there are a plurality of transport elevators, the plurality of transport elevators are arranged at intervals along a second direction, and the second direction intersects the first direction; and
the plurality of power distribution units are divided into a plurality of groups, and each of the plurality of groups of the power distribution units are arranged on the two sides of the first end of one of the plurality of transport elevators; and the plurality of data units are divided into a plurality of groups, and each of the plurality of groups of the data units are arranged on the two sides of the second end of one of the plurality of the transport elevators.

5. The data center according to claim 4, wherein the first layer architecture further comprises a plurality of incoming units arranged on two sides of the plurality of power distribution units along the first direction; each of the plurality of incoming units comprises an inlet box and a high-voltage incoming device arranged inside the inlet box; and/or
the first layer architecture further comprises a plurality of fresh air units arranged on the two sides of the plurality of power distribution units along the first direction; each of the plurality of fresh air units comprises a fresh air box and a fresh air device arranged in the fresh air box, the fresh air device is communicated with the first layer structure and outside world, and the fresh air device is configured to ventilate the first layer structure; and/or
the first layer architecture further comprises a super-core machine room, the super-core machine room comprises a super-core box and a super-core server group arranged in the super-core box; and the super-core machine room is arranged on at least one side of the plurality of power distribution units along the first direction.

6. The data center according to claim 4, wherein the power distribution device group comprises a medium-voltage power distribution module and a low-voltage power distribution module electrically connected to each other, both the medium-voltage power distribution module and the low-voltage power distribution module extend along the first direction, and the medium-voltage power distribution module and the low-voltage power distribution module are arranged at intervals along the second direction intersecting the first direction.

7. The data center according to claim 6, wherein the low-voltage power distribution module comprises a transformer, an incoming cabinet, an uninterruptible power supply (UPS), and an outgoing cabinet sequentially arranged along the first direction; and/or
the medium-voltage power distribution module comprises a medium-voltage power distribution cabinet and a power conversion system (PLC) sequentially arranged along the first direction.

8. The data center according to claim 4, wherein the data server group comprises a plurality of data cabins arranged at intervals in an array, each of the plurality of data cabins comprises a cabin body and an IT cabinet and a wind wall arranged in an inner cavity of the cabin body, the IT cabinet is arranged along the first direction, the wind wall is spaced on one side of the IT cabinet along the second direction, and an air duct for air flow is formed between the IT cabinet and the wind wall.

9. The data center according to claim 8 further comprising a third layer architecture, wherein the third layer architecture is arranged above the second layer architecture, and the third layer architecture comprises a plurality of outdoor units arranged in an array, and each of the plurality of outdoor units is communicated with the wind wall.

10. The data center according to claim 4, wherein the first layer architecture further comprises a first auxiliary unit, the plurality of power distribution units are wrapped around an outer side of the first auxiliary unit, and the first auxiliary unit comprises at least one of a first sanitation room, a storage room, a duty room, a fire control room, a first strong or weak electricity room, an entrance hall, and an unloading hall;
the second layer architecture further comprises a second auxiliary unit, the plurality of data units are wrapped around an outer side of the second auxiliary unit, the second auxiliary unit comprises at least one of a second sanitation room, a second strong or weak electricity room, an operation and maintenance room, a fresh air room, and a weak electricity machine room; and
the transport elevator connects the first auxiliary unit and the second auxiliary unit.
